(19) United States
(12) Patent Application Publication
(10) Pub. No.: US 2015/0352521 A1
(43) Pub. Date: Dec. 10, 2015

(54) GETTERING AGENT, ABSORPTIVE FILM COMPRISING THE SAME AND ORGANIC ELECTRONIC DEVICE (As Amended)

(71) Applicant: LG CHEM, LTD., Yeongdeungpo-gu, Seoul (KR)

(72) Inventors: Su Hee LEE, Daejeon (KR); Won Bae BYUN, Daejeon (KR); Dong Hwan KIM, Daejeon (KR); Cheol Hee PARK, Daejeon (KR); Chee Sung PARK, Daejeon (KR)

(73) Assignee: LG CHEM, LTD., Yeongdeungpo-gu, Seoul (KR)

(21) Appl. No.: 14/759,874

(22) PCT Filed: Nov. 21, 2014
(86) PCT No.: PCT/KR2014/011248

§ 371 Date: Jul. 8, 2015

(30) Foreign Application Priority Data
Nov. 21, 2013 (KR) 10-2013-0142079

(51) Int. Cl. B01J 20/28; B01J 20/04; H01L 51/52

(52) U.S. Cl. CPC B01J 20/28016; H01L 51/5259; H01L 51/5206; H01L 51/5221; H01L 51/5218; H01L 51/5234; B01J 20/28007; B01J 20/041; B01J 20/28026; H01L 2251/303; H01L 2251/301; H01L 2251/5315; H01L 2251/5307

(57) ABSTRACT

Provided are a gettering agent, an absorptive film including the same, and an organic electronic device. In detail, the absorptive film including the gettering agent of the present application is provided on the front side and/or back side of the organic electronic device, and effectively absorbs and blocks moisture, thereby improving the lifespan and durability of the organic electronic device. In addition, the gettering agent of the present application uses a moisture absorbent particle having a nano size to secure transparency of the absorptive film, thereby implementing a top emitting device and also absorbing moisture in the atmosphere during the manufacturing process. Therefore, it is possible to solve the problem of losing the total amount of moisture absorption.

### TECHNICAL FIELD

The present application relates to a gettering agent, an absorptive film including the same, and an organic electronic device.

### BACKGROUND ART

An organic electronic device (OED) includes one or more layers of an organic material that can conduct an electric current. A type of the organic electronic device includes an organic light emitting device (OLED), an organic solar cell, an organic photoconductor (OPC), or an organic transistor.

Generally, the organic light emitting device, which is a representative organic electronic device, typically includes a substrate, a first electrode layer, an organic layer, and a second electrode layer in order. In the structure that is known as a bottom emitting device, the first electrode layer may be formed as a transparent electrode layer and the second electrode layer may be formed as a reflective electrode layer. In addition, in the structure that is known as a top emitting device, the first electrode layer may be formed as a reflective electrode layer and the second electrode layer may be formed as a transparent electrode layer. An electron and a hole injected by an electrode layer may be recombined on an emitting layer that is provided on the organic layer, thereby generating light. The light may be emitted to the side of the substrate in the bottom emitting device and may be emitted to the side of the second electrode layer in the top emitting device.

There is durability as an important issue to be considered in an organic electronic device. It is very easy to oxidize an organic layer or electrode due to foreign materials, such as, moisture or oxygen, and thus, it is important to secure durability against environmental factors. In this regard, Patent Documents 1 to 4 suggest the structure that can block the penetration of foreign materials.

### PRIOR ART DOCUMENT

### Patent Document

Patent Document 1: U.S. Pat. No. 6,226,890

Patent Document 2: U.S. Pat. No. 6,808,828

Patent Document 3: Japanese Laid-Open Patent Publication No. 2000-145627

Patent Document 4: Japanese Laid-Open Patent Publication No. 2001-252505

### DISCLOSURE

### Technical Problem

The present invention is directed to providing a gettering agent, which is provided on a front side or back side of an organic electronic device and effectively absorbs and blocks moisture, and thus, can improve durability and lifespan of the organic electronic device, and to providing an absorptive film including the gettering agent.

### Technical Solution

The present application relates to a gettering agent. The gettering agent may be applied to sealing or encapsulating an organic electronic device, such as an OLED, for example.

In the present specification, the term, “organic electronic device” refers a product or device having a structure that includes an organic material layer generating an alternating current of electric charge using a hole and an electron between a pair of mutually-opposite electrodes, and examples thereof may include a photovoltaic device, a rectifier, a transmitter, and an organic light emitting device (OLED), but the present invention is not limited thereto. In one example of the present invention, the organic electronic device may be an OLED.

An exemplary gettering agent includes a first moisture absorbent particle and a second moisture absorbent particle surrounding the surface of the first moisture absorbent particle. In one example, the second moisture absorbent particle may have an absorbing property, which is a rate of moisture absorption lower than that of the first moisture absorbent particle. In addition, the average particle size of the first moisture absorbent particle may be within the range of 10 nm to 100 nm.

In one example, the gettering agent is maintained at 25° C. and a relative humidity of 70% for 1 hour in a state of having a moisture content of 0 to 0.1 wt %, and then, the moisture content calculated in the gettering agent may be 8 wt % or less or 7 wt % or less. In the present specification, the moisture content in the gettering agent after maintaining for 1 hour may be defined as an initial rate of moisture absorption of the gettering agent, and the lower limit thereof is not particularly limited, but may be 0 wt %, 0.1 wt %, or 1 wt %. In the present application, it is possible to suppress sudden moisture absorption by the gettering agent during an initial process as described above, and thus, the moisture absorbent particle having a particle size of a nano size may form the gettering agent. Therefore, it is possible to implement the transparency of an absorptive film including the gettering agent.

In one example, the gettering agent of the present application may satisfy the following Equation 1.

Y/X≧7 [Equation 1]

In Equation 1, X represents the moisture content in a gettering agent, which is calculated after the gettering agent in the state of having the moisture content of 0 to 0.1 wt % is maintained at 25° C. and a relative humidity of 70% for 1 hour. In addition, Y represents the moisture content in a gettering agent, which is calculated after the gettering agent in the state of having the moisture content of 0 to 0.1 wt % is maintained at 25° C. and a relative humidity of 70% for 72 hours. In other words, according to the gettering agent of the present application, it is possible to maintain an initial rate of moisture absorption to be low, and also, the total amount of moisture that can be absorbed by the gettering agent to be high. Here, Y/X may be 7 to 30 or 8 to 25.

In one example, the rate of moisture absorption of the second moisture absorbent particle may be lower than the rate of moisture absorption of the first moisture absorbent particle. As described above, by the second moisture absorbent particle having a low rate of moisture absorption, which is provided on the surface of the first moisture absorbent particle, the sudden moisture absorption may be suppressed during preparing a gettering agent under a general atmosphere environment. In one example, the moisture content in the first moisture absorbent particle, which is calculated after the first moisture absorbent particle in the state of having the moisture content of 0 to 0.1 wt % is maintained at 25° C. and a relative humidity of 70% for 1 hour, may be 10 wt % to 30 wt %, 10 wt % to 25 wt %, 11 wt % to 23 wt %, or 12 wt % to 20 wt %. In addition, the moisture content in the second moisture absorbent particle, which is calculated after the second moisture absorbent particle in the state of having the moisture content of 0 to 0.1 wt % is maintained at 25° C. and a relative humidity of 70% for 1 hour, may be 1 wt % to 9 wt %, 1 wt % to 8 wt %, 1 wt % to 7 wt %, 1 wt % to 6 wt %, 2 wt % to 5 wt %, or 2.5 wt % to 4.5 wt %. The moisture content may refer to a rate of moisture absorption that absorbs moisture by reacting the moisture absorbent particle with atmospheric moisture over time.

In a specific example of the present application, the rate of moisture absorption of the first moisture absorbent particle, which is calculated after the first moisture absorbent particle in the state of having the moisture content of 0 to 0.1 wt % is maintained at 25° C. and a relative humidity of 70% for 1 hour, may be 2 times to 20 times, 2 times to 16 times, 3 times to 12 times, or 3 times to 10 times higher than the rate of moisture absorption of the second moisture absorbent particle. The second moisture absorbent particle may be located on the surface of the first moisture absorbent particle, and thus, directly in contact with the moisture in the air, and by controlling the rate of moisture absorption of the second moisture absorbent particle as described above, it may be possible to provide a reliable absorptive film to be desired. In other words, since the second moisture absorbent particle is exposed in the air during performing the process, it is possible to control the sudden moisture absorption by the second moisture absorbent particle having a relatively low initial rate of moisture absorption, and also, after completing the process, the absorbent film including the gettering agent can implement the effective block of moisture absorption by the first moisture absorbent particle having a high rate of moisture absorption. In addition, by controlling the sudden moisture absorption as described above, the absorbent particle may be formed in a nano size. In other words, in general, the particle size of the absorbent particle used for a gettering agent is 0.5 to 2 μm. When the particle size thereof is smaller than the above size, the absorbent particle suddenly reacts with atmospheric moisture during performing the process, thereby reducing the total amount of moisture absorption. According to the present application, the sudden moisture absorption may be suppressed as described above, and thus, the moisture absorbent particle having a particle size of a nano size may form a gettering agent. Therefore, it is possible to implement the transparency of absorptive film including the gettering agent. By such a transparent absorptive film, it is possible to implement an OLED in a way of top-emitting.

In the present specification, the term, “moisture absorbent particle” or “moisture absorbing particle” is a composition that forms a gettering agent, and may refer to the first moisture absorbent particle or the second moisture absorbent particle that is claimed by the present application and also to a particle itself, in which the second moisture absorbent particle surrounds the surface of the first moisture absorbent particle.

In one example, the average particle size of the first moisture absorbent particle may be 10 nm to 100 nm, 10 nm to 90 nm, 10 nm to 80 nm, 10 nm to 70 nm, 10 nm to 60 nm, 10 nm to 50 nm, or 20 nm to 40 nm. Here, the particle size of the particle may be measured by a scanning electron microscope (SEM) image, for example. When the average particle size of the first moisture absorbent particle is less than 10 nm, there is a problem in that a specific surface area is very large, and thus, it is difficult to uniformly disperse the particles in a solvent, thereby having an adverse effect on workability. When the average particle size of the first moisture absorbent particle exceeds 100 nm, it is difficult to secure the transparency during manufacturing an absorptive film with a gettering agent. In addition, in one example, the average particle size of the second moisture absorbent particle may be 5 nm to 20 nm, 5 nm to 18 nm, 6 nm to 16 nm, 6 nm to 14 nm, or 8 nm to 12 nm, and may surround the surface of the first moisture absorbent particle. When the average particle size of the second moisture absorbent particle is less than 5 nm, it is difficult to effectively control the sudden moisture absorption of the moisture during processing the process, because the thickness of the particle surrounding the surface of the first moisture absorbent particle is too thin. When the average particle size of the second moisture absorbent particle exceeds 20 nm, it is difficult to effectively block the moisture and also to secure the transparency of the absorptive film after manufacturing a final absorptive film.

Especially, the absorptive film including the gettering agent may secure the transparency due to the first moisture absorbent particle and the second moisture absorbent particle, which are controlled to have a specific size. Therefore, the absorptive film may be positioned on the back side and also on the front side that emits light during encapsulating an organic electronic device, and thus, it is possible to implement a top emitting device without largely changing the structure and manufacturing process of a bottom emitting device that is currently commercialized. In addition, the absorptive films are on both sides, and thus, it is effective to absorb and block moisture.

In a specific example of the present application, the first moisture absorbent particle or the second moisture absorbent particle may be a metallic oxide or a metallic salt. For example, the first or second moisture absorbent particle may be selected from the group consisting of CaO, MgO, CaCl₂, CaCO₃, CaZrO₃, CaTiO₃, SiO₂, Ca₂SiO₄, MgCl₂, P₂O₅, Li₂O, Na₂O, BaO, Li₂SO₄, Na₂SO₄, CaSO₄, MgSO₄, CoSO₄, Ga₂(SO₄)₃, Ti(SO₄)₂, NiSO₄, SrCl₂, YCl₃, CuCl₂, CSF, TaF₅, NbF₅, LiBr, CaBr₂, CeBr₃, SeBr₄, VBr₃, MgBr₂, BaI₂, MgI₂, Ba(ClO₄)₂, and Mg(ClO₄)₂, but the present invention is not limited thereto, and may be used without limit as long as it satisfies the above moisture absorption rate or the difference of the moisture absorbent rates. Therefore, the first moisture absorbent particle and the second moisture absorbent particle, which satisfy the above moisture absorption rate and the difference of moisture absorption rates, may be easily selected by one person skilled in the art. In one example, CaO may be used as the first moisture absorbent particle and MgO may be used as the second moisture absorbent particle, but the present invention is not limited thereto.

In one example, the second moisture absorbent particle may be included in the amount of 5 to 20 parts by weight, 5 to 18 parts by weight, or 8 to 15 parts by weight with respect to 100 parts by weight of the first moisture absorbent particle. By controlling the content of the second moisture absorbent particle to be within the above range, it is possible to effectively surround the first moisture absorbent particle and to control an initial rate of moisture absorption to be in the proper range.

In the present application, a method for performing the surface treatment of the first moisture absorbent particle with the second moisture absorbent particle is as follows. The precursor of the first moisture absorbent particle is added in an organic solvent, and then, the agglomerated powder particles are dispersed by a ball mill process. To the dispersed slurry thus obtained, 0.5 to 3 wt % of the alkoxide compound precursor of the second moisture absorbent particle is added, and then, stirred. 0.1 to 0.5 wt % of an acetic acid solution is added thereto, and then, the solution thus obtained is further stirred to perform hydrolysis. Since then, the reactant is separated by a centrifuge so as to separate a solid content and a solvent. The solid content powder is dried in a vacuum drier while maintaining the temperature at 80° C., and then, is subjected to calcinations at 700° C. under a nitrogen atmosphere to obtain the moisture absorbent particle, in which the second moisture absorbent particle is treated on the surface of the first moisture absorbent particle.

In addition, the present application relates to an absorptive film. The absorptive film may have a gettering layer including the gettering agent described above. The gettering layer may have a shape of film or sheet. Such a gettering layer may be used for encapsulating an organic electronic device.

The absorptive film may further include a substrate film or a releasing film (in some cases, the film may be referred to hereinafter as “a first film”), may have the structure, in which the gettering layer is formed on the substrate film or the releasing film. In addition, the structure may further include a substrate or releasing film (in some cases, the film may be referred to hereinafter as “a second film”) formed on the gettering layer.

FIG. 1 illustrates a cross-sectional diagram of an exemplary absorptive film.

As illustrated in FIG. 1, an absorptive film 1 may include a gettering layer 11 formed on a substrate or releasing film 12. The absorptive film may have the structure that includes only a gettering layer in a shape of a film or sheet maintaining a solid phase or semi-solid phase at room temperature because of having the gettering agent without a supporting substrate, such as a substrate or releasing film; the structure having the gettering layer being formed on both sides of one substrate or releasing film; or the structure, in which a substrate or releasing film is formed on both sides of the gettering layer (not illustrated in drawings).

A specific type of the first film is not particularly limited. For example, as the first film, a plastic film may be used. Examples of the first film may include a polyethyleneterephthalate film, a polytetrafluoroethylene film, a polyethylene film, a polypropylene film, a polybutene film, a polybutadiene film, a vinyl chloride copolymer film, a polyurethane film, an ethylene-vinyl acetate film, an ethylene-propylene copolymer film, an ethylene-acrylic acid ethyl copolymer film, an ethylene-acrylic acid methyl copolymer film, or a polyimide film.

When the first film is a releasing film, a proper release treatment may be performed on one side or both sides of the plastic film described above. Examples of the releasing agent that is used for a release treatment may include an alkyd-based releasing agent, a silicon-based releasing agent, a fluorine-based releasing agent, an unsaturated ester-based releasing agent, a polyolefin-based releasing agent, or an wax-based releasing agent. In consideration of heat resistance, among them, an alkyd-based releasing agent, a silicon-based releasing agent, or a fluorine-based releasing agent is generally used, but the present invention is not limited thereto.

A type of the second film is not particularly limited, either. For example, as the second film, a type that is the same as the first film or different from the first film may be used within the exemplified range for the first film described above.

The thickness of the first or second film is not particularly limited. In one example, the thickness of the first film may be about 50 μm to 500 μm or 100 μm or 200 μm. Within the above range, the process for manufacturing a gettering agent or an organic electronic device may be effectively automated, and also it is financially lucrative.

The thickness of the second film is not particularly limited, either. For example, the thickness of the second film may be the same as the thickness of the first film or may be controlled to be relatively thinner or thicker than the first film.

The thickness of the gettering layer is not particularly limited, and may be properly selected in consideration of a use thereof. For example, the thickness of the gettering layer may be about 5 μm to 200 μm. For example, the thickness of the gettering layer may be controlled in consideration of an embedding property, workability, or economic feasibility when being used as an encapsulant for an organic electronic device.

In addition, the absorptive film may have excellent light transmittance in the visible ray area. In one example, the present application may exhibit 88% or more of light transmittance with respect to the visible ray area. In the present application, the absorptive film including the gettering agent may maintain the transparency, excellently. For example, the gettering layer, which is formed by applying and drying the gettering agent prepared by combining the first moisture absorbent particle and the second moisture absorbent particle that are controlled to have a specific size, to be 50 μm of the thickness after drying, may have the light transmittance of 88% or more, 89% or more, 90% or more, 91% or more, or 92% or more, with respect to the visible ray area. The light transmittance may be measured at 440 nm using a UV/Vis spectrometer.

In addition, the absorptive film may exhibit excellent light transmittance and also low haze. In one example, when the first moisture absorbent particle and the second moisture absorbent particle are combined as described above, it is possible to provide the absorptive film having low haze. For example, the gettering layer that is formed under the same condition as the condition for measuring light transmittance may exhibit the haze of less than 3%, less than 2.9%, or less than 2.8%. The haze may be measured according to a standard test method of ASTM D 1003 using a haze meter.

In a specific embodiment of the present application, the gettering layer of the absorptive film may include a base resin. In one example, the base resin may be a curable resin. As the curable resin, a heat-curable resin, an active energy ray-curable resin, or a hybrid-curable resin, which is known in the art, may be used. In the present specification, “the heat-curable resin” may refer to a resin cured by an aging process or supply of proper heat, “the active energy ray-curable resin” may refer to a resin cured by irradiation of an active energy ray, and “the hybrid-curable resin” may refer to a resin cured by performing the curing mechanisms of heat-curable resin and active energy ray-curable resin at the same time or in order. In addition, here, examples of the active energy ray may include microwaves, IR, UV, X rays, and gamma rays, a particle beam, such as, an alpha-particle beam, a proton beam, a neutron beam, or an electron beam, or the like.

Examples of the curable resin may include, as a resin that can exhibit an adhesive property after being cured, the resin including one or more functional groups or regions that can be cured by heat, such as a glycidyl group, an isocyanate group, a hydroxyl group, a carboxyl group, or an amide group, or the resin including one or more functional groups or regions that can be cured by the irradiation of the active energy rays, such as an epoxide group, a cyclic ether group, a sulfide group, an acetal group, or a lactone group. Examples of the curable resin may include an acrylic resin, a polyester resin, an isocyanate resin, or an epoxy resin, which has one or more functional groups or regions as described above, but the present invention is not limited thereto.

In one example, an epoxy resin may be used as the curable resin. The epoxy resin may be an aromatic-based or aliphatic-based epoxy resin. As the epoxy resin, a heat-curable epoxy resin may be used, or an active energy ray-curable resin, which is cured by a cationic polymerization reaction by the irradiation of active energy rays, for example, may be used.

The epoxy resin according to one example may have an epoxy equivalent of 150 g/eq to 2,000 g/eq. Within the above-described epoxy equivalent, the properties, such as, a glass transition temperature or an adhesive performance of the cured product may be maintained in a proper range.

A type of a curing agent may be properly selected and used according to a type of a curable resin or the functional group that is included in the resin.

In one example, when the curable resin is an epoxy resin, as a curing agent, the curing agents of the epoxy resins that are known in the art, for example, an amine curing agent, an imidazole curing agent, a phenol curing agent, a phosphorus curing agent, or an acid anhydride curing agent, may be used alone or in combination of two or more thereof, but the present invention is not limited thereto.

In one example, as the curing agent, an imidazole compound that is a solid phase at room temperature and has a melting point or a decomposition temperature of 80° C. or higher may be used. Examples of the compound may include 2-methyl imidazole, 2-heptadecyl imidazole, 2-phenyl imidazole, 2-phenyl-4-methyl imidazole, or 1-cyanoethyl-2-phenyl imidazole, but the present invention is not limited thereto.

The content of the curing agent may be selected according to a type or a rate of the composition, for example, a curable resin. For example, the curing agent may be included in the amount of 1 part by weight to 20 parts by weight, 1 part by weight to 10 parts by weight, or 1 part by weight to 6 parts by weight, with respect to 100 parts by weight of the curable resin. However, the weight rate may be changed according to a type and ratio of the curable resin or the functional group of the resin, or a crosslink density to be implemented.

When the curable resin is an epoxy resin that can be cured by the irradiation of the active energy rays, for example, a cationic photo-polymerization initiator may be used as an initiator.

As the cationic photo-polymerization initiator, an onium salt or an organometallic salt-based ionized cationic initiator or an organosilane or latent sulfonic acid-based non-ionized cationic photo-polymerization initiator may be used. Examples of the onium salt-based initiator may include a diaryliodonium salt, a triarylsulfonium salt, an aryldiazonium salt, or the like; examples of the organometallic salt-based initiator may include iron arene, or the like; examples of the organosilane-based initiator may include o-nitrobenzyl triaryl silyl ether, triaryl silyl peroxide, acyl silane, or the like; and examples of latent sulfonic acid-based initiator may include a-sulfonyloxy ketone, a-hydroxymethylbenzoin sulfonate, or the like, but the present invention is not limited thereto.

In one example, as a cationic initiator, an ionized cationic photo-polymerization initiator may be used.

The content of the initiator may be changed according to a type and ratio of the curable resin or the functional group of the resin, or a crosslink density to be implemented as the curing agent. For example, the initiator may be combined in the ratio of 0.01 part by weight to 10 parts by weight or 0.1 part by weight to 3 parts by weight, with respect to 100 parts by weight of the curable resin. When the content of the initiator is excessively small, the curing may not be performed sufficiently and when the content of the initiator is excessively large, the content of ionic materials increases after curing, thereby decreasing the durability of adhesive or forming a conjugate acid due to properties of the initiator, and thus it is unfavorable in terms of optical durability and also corrosion may be generated in some substrates. Therefore, in consideration of those points, the content of the initiator may be selected in the proper content range.

As described above, the absorptive film of the present application may include a gettering layer, and the gettering layer may further include a binder resin. A type of the binder resin is not particularly limited as long as it has compatibility with other resins, such as a base resin. As the binder resin, a phenoxy resin, an acrylate resin, or a high molecular weight epoxy resin may be used. Here, the high molecular weight epoxy resin may refer to a resin having a weight average molecular weight of about 2,000 to 70,000 or 4,000 to 6,000, for example. Examples of the high molecular weight epoxy resin may include a solid bisphenol A-type epoxy resin or a solid bisphenol F-type epoxy resin. As the binder resin, a rubber component, such as a high polarity functional group-containing rubber or a high polarity functional group-containing reactive rubber may be used. In one example, as the binder resin, a phenoxy resin may be used.

When the binder resin is included, the ratio thereof is controlled according to a desired physical property, but is not particularly limited. For example, the binder resin may be included in the amount of about 200 parts by weight or less, about 150 parts by weight or less, or about 100 parts by weight or less, with respect to 100 parts by weight of the base resin. When the ratio of the binder resin is 200 parts by weight or less, it is possible to effectively maintain the compatibility with the base resin and to play a role as an adhesive layer.

In addition, the present application relates to an organic electronic device including the absorptive film. The exemplary organic electronic device of the present application includes a substrate, a transparent electrode layer provided on the substrate, an organic layer that is provided on the transparent electrode layer and at least includes an emitting layer, and a reflective electrode layer provided on the organic layer, in which an absorptive film may be provided between the substrate and the transparent electrode layer or on the top of the reflective electrode layer. When the transparent electrode layer and reflective electrode layer are configured as described above, it is possible to implement the bottom emitting device, in which the light generated in the emitting layer of the organic layer is emitted to the side of substrate.

In one embodiment of the present application, the absorptive film may be provided between the substrate and the transparent electrode layer and also on the top of the reflective electrode layer. By further including the absorptive film, an effect of absorbing and blocking moisture from the outside becomes excellent.

In addition, an exemplary organic electronic device of the present application includes a substrate, a reflective electrode layer provided on the substrate, an organic layer that is provided on the reflective electrode layer and at least includes an emitting layer, and an transparent electrode layer provided on the organic layer, in which an absorptive film may be provided on the transparent electrode layer. When the transparent electrode layer and reflective electrode layer are configured as described above, it is possible to implement the top emitting device, in which the light generated in the emitting layer of the organic layer is emitted to the side of transparent electrode layer.

Here, since the light generated in the emitting layer of the organic layer is emitted to the side of the transparent electrode layer, the absorptive film should satisfy the transparency in the case of the top emitting device. The absorptive film according to the present application includes the first moisture absorbent particle and the second moisture absorbent particle having a specific size, and thus, it is possible to implement the top emitting device.

In one specific embodiment of the present application, the absorptive film may be further provided between the reflective electrode layer and the substrate.

The organic electronic device of the present application may have the structure having an organic layer including at least an emitting layer, which is positioned between a hole-injection electrode layer and an electron-injection electrode layer. For example, when the electrode layer on the top of the substrate is a hole-injection electrode layer, the electrode layer on the other side thereof may be an electron-injection electrode layer, and on the contrary, when the electrode layer on the top of the substrate is an electron-injection electrode layer, the electrode layer on the other side thereof may be a hole-injection electrode layer.

The organic layer provided between the electron- and hole-injection electrode layer may include at least one emitting layer. The organic layer may include two or more plurality of emitting layers. When two or more emitting layers are included, the emitting layers may have the structure, in which the layers are divided by an intermediate electrode layer or charge generating layer (CGL) having a charge-generating property.

The emitting layer may be formed using various fluorescence or phosphorescence organic materials that are known in the art, for example. Examples of the materials for forming the emitting layer may include Alq-based materials, such as, tris(4-methyl-8-quinolinolate)aluminum (III) (Alg3), 4-MAlq3 or Gaq3, a cyclopenadiene derivative, such as, C-545T(C₂₆H₂₆N₂O₂S), DSA-amine, TBSA, BTP, PAP-NPA, spiro-FPA, Ph₃Si(PhTDAOXD), or 1,2,3,4,5-pentaphenyl-1,3 -cyclopentadiene (PPCP), DPVBi(4,4′-bis(2,2′-diphenylyinyl)-1,1′-biphenyl), distyrylbenzene or a derivative thereof, or DCJTB(4-(Dicyanomethylene)-2-tert-butyl-6-(1,1,7,7,-tetramethyljulolidyl-9-enyl)-4H-pyran), DDP, AAAP, or NPAMLI; or a phosphorescence material, such as, Firpic, m-Firpic, N-Firpic, bon₂Ir(acac), (C₆)₂Ir(acac), bt₂Ir(acac), dp₂Ir(acac), bzq₂Ir(acac), bo₂Ir(acac), F₂Ir(bpy), F₂Ir(acac), op₂Ir(acac), ppy₂Ir(acac), tpy₂Ir(acac), Flrppy(fac-tris[2-(4,5′-difluorophenyl)pyridine-C′,N] iridium(III)), or Btp₂Ir(acac)(bis(2-(2′-benzo[4,5-a]thienyl)pyridinato-N,C3′) ridium(acetylactonate)), but the present invention is not limited thereto. The emitting layer may have a host-dopant system including the above materials as a host and perylene, distyrylbiphenyl, DPT, quinacridone, rubrene, BTX, ABTX, or DCJTB as a dopant.

In addition, the emitting layer may be formed by properly using a type exhibiting an emitting property among electron-accepting organic compounds or electron-donating organic compounds.

The organic layer may be formed in various structures, further including other various functional layers that are known in the art as long as it includes an emitting layer. Examples of the layer that can be included in an organic layer may include an electron injection layer, a hole blocking layer, an electron transporting layer, a hole transporting layer, and a hole injection layer.

Various materials for forming a hole or electron injection electrode layer and an organic layer, for example, an emitting layer, an electron injection or transporting layer, and a hole injection or transporting layer, and the methods for manufacturing the same are known in the art, and may be used without limit.

The organic electronic device may further include an encapsulation structure. The encapsulation structure may be a protection structure that blocks the inflow of foreign materials, such as moisture or oxygen, into the organic layer of the organic electronic device. For example, the encapsulation structure may be a can, such as a glass can or a metal can, or a film covering the front side of the organic layer.

FIG. 2 illustrates an exemplary type, in which a substrate 21, a transparent electrode layer 22, an organic layer 23 provided on the transparent electrode layer 22, and a reflective electrode layer 24, which are formed in order, are protected by an encapsulation structure 25 having a can structure, such as a glass can or a metal can, and an absorptive film 26 is provided between the transparent electrode layer 22 and the substrate 21. As illustrated in FIG. 2, the encapsulation structure 25 may be attached on the substrate by an adhesive, for example. In addition, the sides of the organic layer and the electrode layer may be sealed by an adhesive. In such a way, a protection effect may be maximized through an encapsulation structure.

FIG. 3 illustrates an exemplary type, in which a substrate 21, an absorptive film 26, a reflective electrode layer 24, an organic layer 23 formed on the reflective electrode layer 24, a transparent electrode layer 22, and an absorptive film 26, which are formed in order, are protected by an encapsulation structure 25 having a can structure, such as a glass can or a metal can.

### Effects

The present application can provide a reliable film by suppressing sudden moisture absorption of a gettering agent during the process for manufacturing an absorptive film. In addition, the absorptive film including the gettering agent is positioned on the front side or back side of an organic electronic device, and thus, effectively blocks moisture, and thus, the lifespan and durability of the organic electronic device can be improved. In addition, the absorptive film according to the present application secures transparency, and thus, can be positioned even on the side that emits light. Therefore, it is possible to implement a top emitting device.

### DESCRIPTION OF DRAWINGS

FIG. 1 illustrates a diagram illustrating an exemplary absorptive film according to the present application.

FIGS. 2 and 3 illustrate diagrams illustrating an exemplary organic electronic device according to the present application.

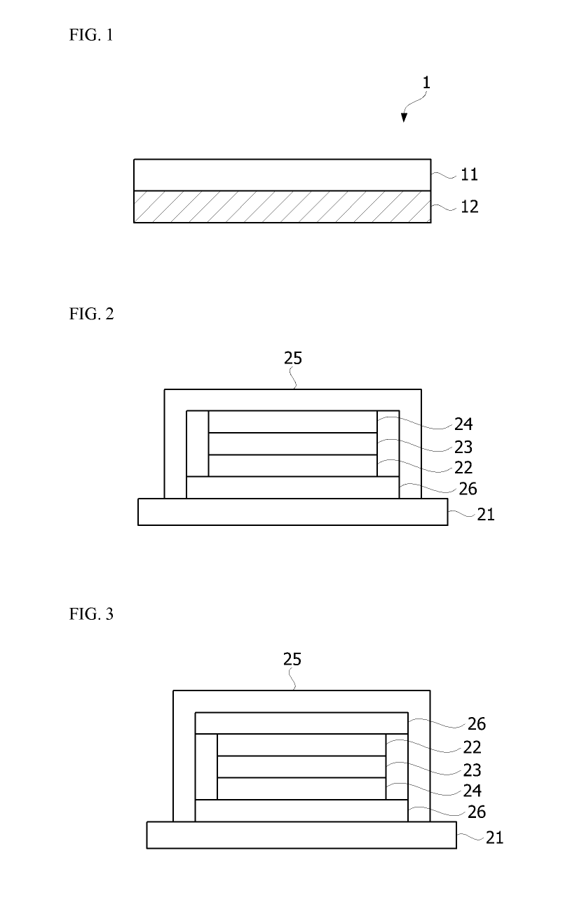

### DESCRIPTION OF REFERENCE NUMERALS

1, 26: absorptive film

11: gettering layer

12: releasing film

21: substrate

22: transparent electrode layer

23: organic layer

24: reflective electrode layer

25: encapsulation structure

### Modes of the Invention

Hereinafter, the present application will be described in more detail with reference of Examples according to the present application and Comparative Examples not according to the present application, but the scope of the present application is not limited to the following Examples.

### EXAMPLE 1

1. Preparation of Moisture Absorbent Particle

A CaO slurry was prepared by adding 3 g of CaO (first moisture absorbent particle) powder having a size of 30 nm to 100 ml of an anhydrous ethanol and then performing a ball mill process for 24 hours. 3 ml of the solution prepared by dissolving Mg(OCH₃)₂ in methanol to be 10 wt % was added to the CaO slurry and then, stirred for 3 hours, such that a second moisture absorbent particle was subjected to the surface treatment of CaO. 0.5 ml of an acetic acid solution was added thereto, and then, further stirred for 2 hours. The reactant thus obtained was separated by using a centrifuge to separate a solid content and a solvent, and then, the solid content was dried in a vacuum dryer device while maintaining the temperature of the device at 80° C. The dried solid content was subjected to calcinations under a nitrogen atmosphere at 700° C. for 15 minutes, such that the surface treatment was performed on the second moisture absorbent particle to have the thickness of 10 nm. The first moisture absorbent particle that was surface-treated with the second moisture absorbent particle was obtained.

2. Preparation of Solution of Gettering Layer

The moisture absorbent particles (the first moisture absorbent particles that were surface-treated with the second moisture absorbent particles) prepared as described above were dispersed in a solvent. In addition, separately, a solution (solid content of 70%), which was prepared by diluting 100 g of an epoxy resin (YD-128, manufactured by Kukdo Chemical) and 70 g of a phenoxy resin (YP-70, manufactured by Dongdo Chemical) with methylethylketone, was prepared, and then, homogenized. 250 g of the ready-made moisture absorbent particle solution was added to the homogenized solution thus obtained, and then, 5 g of imidazole (Shikoku Chemicals) that is a curing agent was added thereto. Since then, the solution thus obtained was stirred at a high speed for 1 hour to prepare a solution of gettering layer.

3. Preparation of Absorptive Film

The solution of gettering layer that was prepared as described above was applied on the releasing side of releasing PET using a comma coater and dried in a dryer at 130° C. for 3 minutes to obtain an absorptive film including a gettering layer having a thickness of 50 μm.

### EXAMPLE 2

A moisture absorbent particle and an absorptive film including the same were prepared in the same method as Example 1, except that 0.5 ml of the solution that was dissolved with 10 wt % of Mg(OCH₃)₂ was added to methanol.

### COMPARATIVE EXAMPLE 1

An absorptive film was prepared in the same method as Example 1, except that CaO powder having a size of 30 nm was not subjected to a surface treatment.

### COMPARATIVE EXAMPLE 2

An absorptive film was prepared in the same method as Example 1, except that CaO powder having a size of 200 nm was not subjected to a surface treatment.

### COMPARATIVE EXAMPLE 3

An absorptive film was prepared in the same method as Comparative Example 1, except that CaO powder having a size of 1 μm was used.

### EXPERIMENTAL EXAMPLE 1

1 g of each of the gettering agents (0 wt % of the moisture content) prepared in Examples and Comparative Examples was added to a vial, and then, the vial without putting a top thereon was put in a constant temperature and humidity chamber. The constant temperature and humidity chamber was maintained at the temperature of 25° C. and the humidity of 70%. The time-based masses of the vials containing the samples were measured, and the moisture content was measured initially 1 hour after the beginning, and then, was defined as an initial rate of moisture absorption and compared. It was confirmed that 72 hours later, there were no mass increases. At this time, the amount of moisture absorption was defined as a total amount of moisture absorption, and then, compared.

### EXPERIMENTAL EXAMPLE 2

The light transmittances of the absorptive films prepared in Examples and Comparative Examples were measured at 440 nm using a UV-Vis spectrometer, and the hazes thereof were measured according to the standard test method of ASTM D 1003.

TABLE 1

| | Initial rate | Total amount |
|---|---|---|
| | of moisture | of moisture |
| | absorption (wt %) | absorption (wt %) |
| Example 1 | 4.3 | 34.3 |
| Example 2 | 3.2 | 34.1 |
| Com. Example 1 | 11.6 | 34.9 |
| Com. Example 2 | 8.2 | 34.5 |
| Com. Example 3 | 4.1 | 34.3 |

TABLE 2

| | Light transmittance (%) | Haze (%) |
|---|---|---|
| Example 1 | 90 | 2.3 |
| Example 2 | 90 | 2.4 |
| Com. Example 1 | 88.4 | 4.1 |
| Com. Example 2 | 87.3 | 6.2 |
| Com. Example 3 | 65.4 | 21.6 |

As listed in Table 1, it can be confirmed that when the moisture absorbent particle having a nano size is the types of the moisture absorbent particles prepared in Examples 1 and 2, the initial rates of moisture absorption were 4.3 wt % and 3.2 wt %, respectively, which was significantly suppressed as compared with Comparative Examples 1 and 2 without any sort of treatments. However, it can be confirmed that the total amount of moisture absorption after a substantial amount of time has lapsed is barely decreased. For this reason, it can be expected that the decrease in the amount of moisture absorption of the moisture absorbent particle according to the present application can be prevented even when a process for manufacturing a device is performed in the atmosphere, not the extremely dried atmosphere.

In addition, as listed in Table 2, it can be confirmed from the result of measuring light transmittances and hazes of the absorptive films prepared in Examples and Comparative Examples that the absorptive films of Examples 1 and 2 using the particles of the present application exhibit excellent light transmittances, but the light transmittances of the films of Comparative Examples 2 and 3 are significantly decreased.

From the results of Experimental Examples, it can be confirmed that it is possible to prepare a transparent absorptive film that can be applied to a top-emission OLED using a moisture absorbent particle having a nano size, and by forming a protection layer with a moisture absorbent particle having a low rate of moisture absorption on the surface of a first nano moisture absorbent particle, it is possible to obtain an effect of suppressing the particle alteration generated due to a sudden moisture absorption during performing a device-manufacturing process in the general atmosphere.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

1. A gettering agent comprising a first moisture absorbent particle, which has an average particle size in a range of 10 nm to 100 nm; and a second moisture absorbent particle, which surrounds a surface of the first moisture absorbent particle and has a lower rate of moisture absorption than the first moisture absorbent particle.

2. The gettering agent of claim 1, having 8 wt % or less of a moisture content, which is calculated after the gettering agent in a state of having the moisture content of 0 to 0.1 wt % is maintained at 25° C. and a relative humidity of 70% for 1 hour.

3. The gettering agent of claim 1, satisfying the following Equation 1:
Y/X≧7 [Equation 1]
where, in Equation 1, X represents a moisture content in a gettering agent, which is calculated after the gettering agent in a state of having the moisture content of 0 to 0.1 wt % is maintained at 25° C. and a relative humidity of 70% for 1 hour, and Y represents the moisture content in a gettering agent, which is calculated after the gettering agent in the state of having the moisture content of 0 to 0.1 wt % is maintained at 25° C. and a relative humidity of 70% for 72 hours.

4. The gettering agent of claim 1, wherein the first moisture absorbent particle has 10 wt % to 30 wt % of a moisture content, which is calculated after the first moisture absorbent particle in a state of having the moisture content of 0 to 0.1 wt % is maintained at 25° C. and a relative humidity of 70% for 1 hour.

5. The gettering agent of claim 1, wherein the second moisture absorbent particle has 1 wt % to 9 wt % of a moisture content, which is calculated after the second moisture absorbent particle in a state of having the moisture content of 0 to 0.1 wt % is maintained at 25° C. and a relative humidity of 70% for 1 hour.

6. The gettering agent of claim 1, wherein a rate of moisture absorption of the first moisture absorbent particle is 2 times to 20 times higher than a rate of moisture absorption of the second moisture absorbent particle, which are calculated after the first or second moisture absorbent particle in a state of having a moisture content of 0 to 0.1 wt % is maintained at 25° C. and a relative humidity of 70% for 1 hour.

7. The gettering agent of claim 1, wherein an average particle size of the first moisture absorbent particle is within a range of 10 nm to 90 nm.

8. The gettering agent of claim 1, wherein an average particle size of the second moisture absorbent particle is within a range of 5 nm to 20 nm.

9. The gettering agent of claim 1, wherein the first moisture absorbent particle or the second moisture absorbent particle is one or more selected from the group consisting of CaO, MgO, CaCl₂, CaCO₃, CaZrO₃, CaTiO₃, SiO₂, Ca₂SiO₄, MgCl₂, P₂O₅, Li₂O, Na₂O, BaO, Li₂SO₄, Na₂SO₄, CaSO₄, MgSO₄, CoSO₄, Ga₂(SO₄)₃, Ti(SO₄)₂, NiSO₄, SrCl₂, YCl₃, CuCl₂, CsF, TaF₅, NbF₅, LiBr, CaBr₂, CeBr₃, SeBr₄, VBr₃, MgBr₂, BaI₂, MgI₂, Ba(ClO₄)₂, and Mg(ClO₄)₂.

10. The gettering agent of claim 1, wherein the second moisture absorbent particle is comprised in an amount of 5 to 20 parts by weight with respect to 100 parts by weight of the first moisture absorbent particle.

11. An absorptive film comprising a gettering layer having the gettering agent of claim 1.

12. The absorptive film of claim 11, having light transmittance of 88% or more with respect to a visible ray area.

13. The absorptive film of claim 11, wherein a haze is less than 3%.

14. The absorptive film of claim 11, wherein the gettering layer further comprises a base resin.

15. The absorptive film of claim 14, wherein the base resin comprises an acrylic resin, a polyester resin, an isocyanate resin, or an epoxy resin.

16. The absorptive film of claim 11, wherein the gettering layer further comprises 50 parts by weight to 200 parts by weight of a binder resin with respect to 100 parts by weight of a base resin.

17. The absorptive film of claim 16, wherein the binder resin comprises a phenoxy resin, an acrylate resin, or a high molecular weight epoxy resin.

18. An organic electronic device comprising the absorptive film of claim 11.

19. The organic electronic device of claim 18, comprising a substrate, a transparent electrode layer provided on the substrate, an organic layer, which is provided on the transparent electrode layer and at least comprises an emitting layer, and a reflective electrode layer provided on the organic layer,
wherein the absorptive film is provided between the substrate and the transparent electrode layer or on the top of the reflective electrode layer.

20. The organic electronic device of claim 19, wherein the absorptive films are provided between the substrate and the transparent electrode layer and on the top of the reflective electrode layer.

21. The organic electronic device of claim 18, comprising a substrate, a reflective electrode layer provided on the substrate, an organic layer, which is provided on the reflective electrode layer and at least includes an emitting layer, and a transparent electrode layer provided on the organic layer,
wherein the absorptive film is provided on the top of the transparent electrode layer.

22. The organic electronic device of claim 21, further comprising the absorptive film between the reflective electrode layer and the substrate.
